(19) United States
(12) Patent Application Publication
(10) Pub. No.: US 2009/0289674 A1
(43) Pub. Date: Nov. 26, 2009

(54) PHASE-LOCKED LOOP

(76) Inventors: Hong-Sing Kao, Hsinchu County (TW); Tse-Hsiang Hsu, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/126,989

(22) Filed: May 26, 2008

(51) Int. Cl. H03L 7/08

(52) U.S. Cl. 327/157

(57) ABSTRACT

A phase-locked loop includes a phase detector, a charge pump and a controllable oscillator. The phase detector is supplied by a first supply voltage and is utilized for comparing a phase difference between an reference input signal and a feedback signal based on an output signal to generate at least one detect signal. The charge pump is supplied by a second supply voltage, and is utilized for generating a control signal with charge amounts according to the detect signal, where the first supply voltage is different from the second supply voltage. The controllable oscillator is utilized for generating the output signal according to the control signal, wherein a frequency of the output signal is adjusted by the control signal.

### BACKGROUND

The invention relates to a phase-locked loop (PLL), and more particularly, to a phase-locked loop which has a charge pump comprising at least one input/output (I/O) device.

FIG. 1 is a diagram illustrating a related art phase-locked loop 100. The PLL 100 comprises a phase detector (PD) 110, a charge pump (CP) 120, a low-pass filter (LPF) 130, and a voltage-controlled oscillator (VCO) 140, where all transistors in the PLL 100 are supplied by the same supply voltage V_{DD}.

In the PLL 100, the phase detector 110 compares a phase difference between a reference input signal V_{ref} and an output signal Vₒᵤₜ to generate a detect signal V_{PD}, and the charge pump 120 receives the detect signal V_{PD} and generates a control signal V_{c}. Then, the low-pass filter 130 filters the control signal V_{c} to generate a filtered control signal V_{c}′, and the voltage-controlled oscillator 140 generates the output signal Vₒᵤₜ according to the filtered control signal V_{c}′. Since all of the transistors in the PLL are supplied by the same supply voltage V_{DD}, the available range of the control voltage V_{c}, which is generally in proportional to detect signal V_{PD}, is limited by the supply voltage V_{DD}.

In order to provide the output voltage Vₒᵤₜ with a required frequency, a gain K_{VCO} of the voltage-controlled oscillator 140 must be increased, and the jitter of the PLL 100 will become higher due to the increased gain K_{VCO}. FIG. 2 is a diagram illustrating a relationship between the required frequency of the output voltage Vₒᵤₜ and the filtered control voltage V_{c}′. In FIG. 2, lines 202 and 204 represent the relationships of the required frequency of the output voltage Vₒᵤₜ and the filtered control voltage V_{c}′ corresponding to high and low gains K_{VCO}, respectively. Accordingly, the gain K_{VCO} of the voltage-controlled oscillator 140 can be decreased as long as the available range of the control voltage V_{c} is increased, thus lowering the jitter of the PLL 100 while the same required frequency of the output voltage Vₒᵤₜ is obtained.

### SUMMARY

It is therefore one of the objectives of the claimed invention to provide a phase-locked loop comprising a charge pump capable of providing a wider available voltage range of its output, to solve the above-mentioned problem.

According to one embodiment of the present invention, a phase-locked loop comprises a phase detector, a charge pump, and a controllable oscillator. The phase detector is supplied by a first supply voltage and is utilized for comparing a phase difference between a reference input signal and a feedback signal based on an output signal to generate at least one detect signal. The charge pump is supplied by a second supply voltage and is coupled to the phase detector, and is utilized for generating a control signal with charge amounts according to the detect signal, where the first supply voltage is different from the second supply voltage. The controllable oscillator is utilized for generating the output signal according to the control signal, where a frequency of the output signal is adjusted by the control signal. According to another embodiment of the present invention, a phase-locked loop comprises a phase detector, a charge pump, and a controllable oscillator. The phase detector is utilized for comparing a phase difference between a reference input signal and a feedback signal based on an output signal to generate at least one detect signal. The charge pump is utilized for generating a control signal with charge amounts according to the detect signal. The controllable oscillator is utilized for generating the output signal according to the control signal, where a frequency of the output signal is adjusted by the control signal. Additionally, the charge pump comprises at least one I/O device and each transistor included in the phase detector is a core device. These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a related art phase-locked loop.

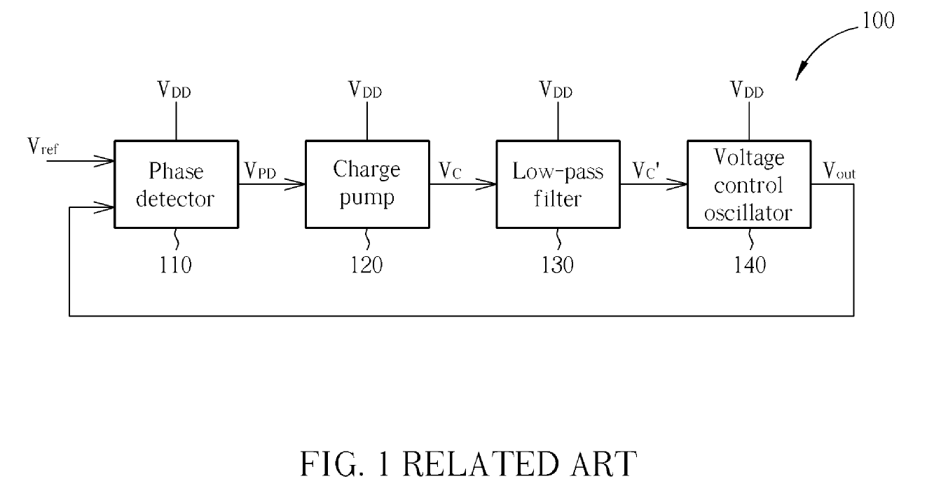

FIG. 2 is a diagram illustrating a relationship between the required frequency of the output voltage and the filtered control voltage.

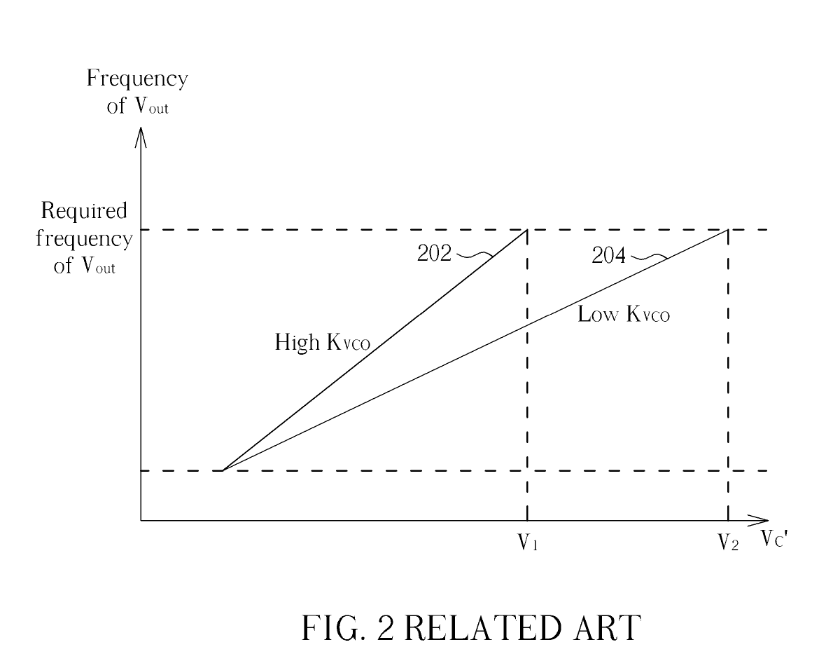

FIG. 3 is a diagram illustrating a phase-locked loop according to an embodiment of the present invention.

FIG. 4 is a circuit diagram illustrating the charge pump shown in FIG. 3.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” The terms “couple” and “couples” are intended to mean either an indirect or a direct electrical connection. Thus, if a first device couples to a second device, that connection may be through a direct electrical connection, or through an indirect electrical connection via other devices and connections.

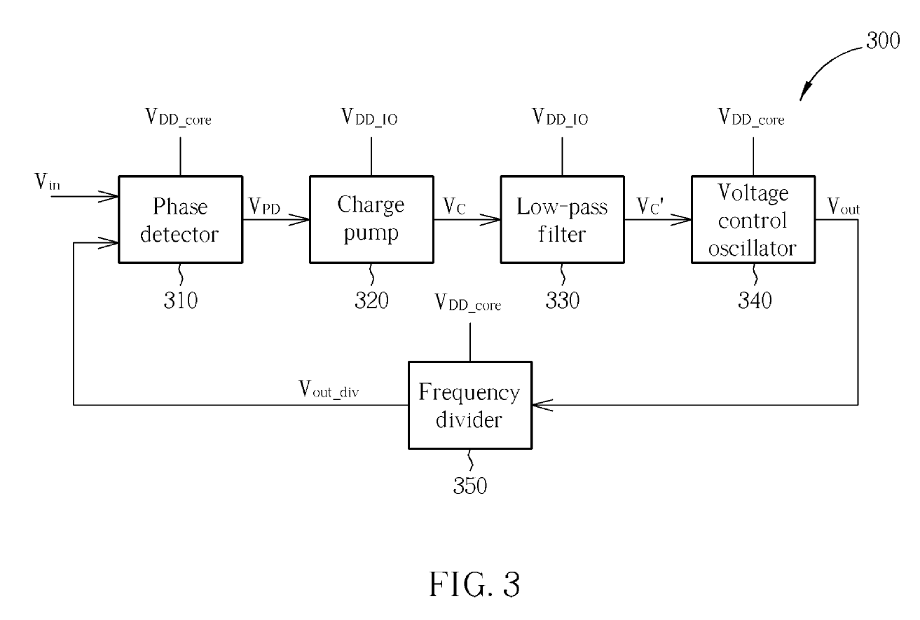

FIG. 3 is a diagram illustrating a phase-locked loop 300 according to an embodiment of the present invention. The phase-locked loop 300 comprises a phase detector 310, a charge pump 320, a filter (in this embodiment, a low-pass filter 330 is an example), a controllable oscillator (in this embodiment, a voltage-controlled oscillator 340 is shown as an example), and a frequency divider 350. All transistors in the phase detector 310 and the frequency divider 350 are core devices, and each of the charge pump 320 and the low-pass filter 330 comprises at least one input/output (I/O) device. Additionally, the phase detector 310, the voltage-controlled oscillator 340, and the frequency divider 350 are supplied by a first supply voltage, e.g. the core supply voltage V_{DD}_{_{—}}_{core}, and the charge pump 320 and the low-pass filter 330 are supplied by the second supply voltage, e.g. the I/O supply voltage V_{DD}_{_{—}}_{IO}, where the second supply voltage V_{DD}_{_{—}}_{IO} is greater than the first supply voltage V_{DD}_{_{—}}_{core}.

In the PLL 300, the phase detector 310 compares a phase difference between a reference input signal V_{ref} and a feedback signal Vₒᵤₜ_{_{—}}_{div} to generate at least one detect signal V_{PD}, and the charge pump 320 generates a control signal V_{c} according to the detect signal V_{PD} to pump charge into or out of the low-pass filter 330. The low-pass filter 330 then filters the control signal V_{c} to generate a filtered control signal V_{c}′, and the voltage-controlled oscillator 340 generates an output signal Vₒᵤₜ according to the filtered control signal V_{c}′, where a frequency of the output signal Vₒᵤₜ is adjusted by the filtered control signal V_{c}′. The frequency divider divides the output signal Vₒᵤₜ to generate the feedback signal Vₒᵤₜ_{_{—}}_{div}. Additionally, in some embodiments, the low-pass filter 330 may be omitted due to special designs or mild technical requirements.

In the PLL 300, because the charge pump 320 comprises the I/O device which is supplied by the second supply voltage V_{DD}_{_{—}}_{IO} greater than that supplies to the phase detector 310, the control voltage V_{c} thus has a relatively wider available voltage range. Therefore, the voltage-controlled oscillator 340 having a low gain K_{VCO} is able to provide the output voltage Vₒᵤₜ of a required frequency, such that the jitter of the PLL 300 can be alleviated.

In this embodiment, in order to receive either the control voltage generated from the charge pump 320 while the low-pass filter 330 is omitted as stated above or the filtered control voltage V_{c}′ generated from the low-pass filter 330, for example, which is also supplied by the I/O supply voltage V_{DD}_{_{—}}_{IO}, the input interface of the voltage-controlled oscillator 340 can be implemented by the I/O devices, and the other parts in the voltage-controlled oscillator 340 can be implemented by the core devices. In such configuration, the voltage-controlled oscillator 340 is still supplied by the first supply voltage V_{DD}_{_{—}}_{core}, which in practice is enough for the voltage-controlled oscillator 340 to successfully function and generate the output signal Vₒᵤₜ.

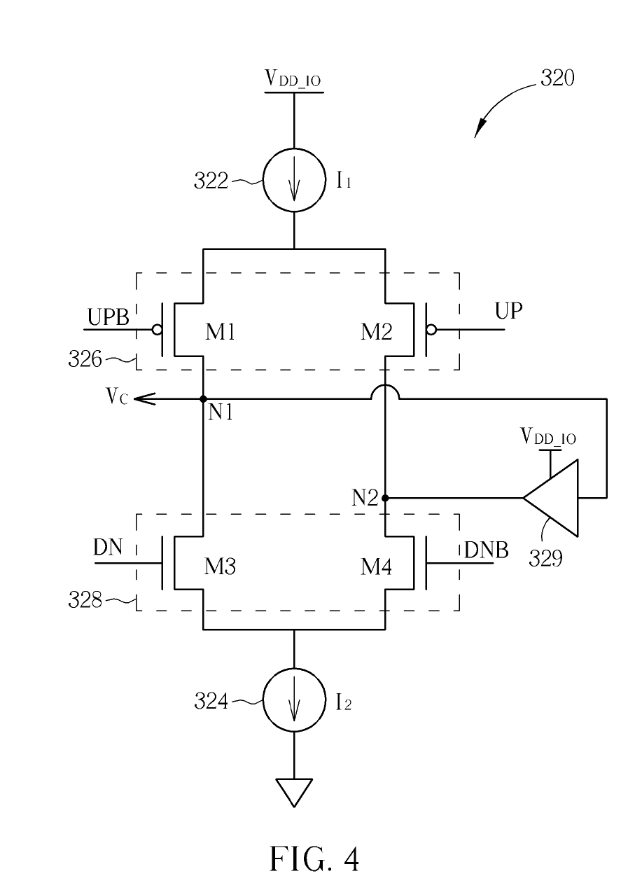

FIG. 4 is a circuit diagram illustrating one embodiment of the charge pump 320 shown in FIG. 3. The charge pump 320 comprises a first current source 322, a first differential pair circuit 326, a second differential pair circuit 328, a second current source 324, and a buffer amplifier 329, where the first differential pair circuit 326 comprises two transistors M1 and M2 (e.g. PMOS transistors), and the second differential pair circuit 328 comprises two transistors M3 and M4 (e.g. NMOS transistors). The first current source 322 is supplied by the second supply voltage V_{DD}_{_{—}}_{IO} and coupled to the first differential pair circuit 326, and is utilized for providing a first current I₁. The second current source 324 is coupled to the second differential circuit 328 and is utilized for providing a second current I₂, and the second differential pair circuit 328 is coupled to the first differential pair circuit 326 at a first node N1 and a second node N2. The buffer amplifier 329 is supplied by the second supply voltage V_{DD}_{_{—}}_{IO} and is coupled between the first node N1 and the second node N2, where the first node N1 serves as an output node of the charge pump 320 for outputting the control signal V_{c}. Additionally, the transistors M1 and M2 and at least one device implemented in the first current source 322 are I/O devices, and the transistors M3 and M4 and devices implemented in the second current source 328 can be core devices. Also, the buffer amplifier 329 comprises at least one I/O device.

In this embodiment, the detect signal V_{PD} generated from the phase detector 310 includes a first detect signal UP and a second detect signal DN, and the charge pump generates the control signal V_{c} according to the first detect signal UP, the second detect signal DN, an inverted first detect signal UPB, and an inverted second detect signal DNB The inverted first detect signal UPB, the first detect signal UP, the second detect signal DN, and the inverted second detect signal DNB are inputted into the gates of transistors M1, M2, M3, M4, respectively. Additionally, voltage levels of the four detect signals UP, UPB, DN, DNB may be either 0 or equal to V_{DD}_{_{—}}_{core}.

Specifically, the I/O device has a higher operating voltage, that is, can be operated by a higher supply voltage (i.e. the high-voltage device). In the other hand, the core device has a lower operating voltage, that is, can be operated by a lower supply voltage (i.e. the low-voltage device). Please note that those skilled in this art will readily understand that the distinction between the core device and the I/O device can be defined by the threshold voltage (Vth) of the transistor, the gate oxide thickness of the transistor, the junction breakdown voltage of the transistor, the well doping density of the transistor, the static leakage current of the transistor, or other suitable characteristics known in the semiconductor field.

Briefly summarized, in the embodiments of the present invention, the charge pump of the phase-locked loop comprises I/O devices, and is supplied by a higher supply voltage. Therefore, the available range of the control voltage generated from the charge pump is wider, and the output signal of a required frequency generated from the voltage-controlled oscillator can be provided by a lower gain with the control voltage of a higher level. As a result, the jitter of the PLL can be alleviated due to the lower gain of the voltage-controlled oscillator.

Those skilled in the art will readily observe that numerous modifications and alterations of the device and method may be made while retaining the teachings of the invention.

What is claimed is:

1. A phase-locked loop (PLL), comprising:
a phase detector, supplied by a first supply voltage, for comparing a phase difference between a reference input signal and a feedback signal based on an output signal to generate at least one detect signal;
a charge pump, supplied by a second supply voltage, for generating a control signal with charge amounts according to the detect signal, wherein the first supply voltage is different from the second supply voltage; and
a controllable oscillator, for generating the output signal according to the control signal, wherein a frequency of the output signal is adjusted by the control signal.

2. The PLL of claim 1, further comprising:
a frequency divider, for dividing the output signal to generate the feedback signal.

3. The PLL of claim 1, further comprising:
a filter, for filtering the control signal before the controllable oscillator, wherein the filter is supplied by the second supply voltage.

4. The PLL of claim 1, wherein the second supply voltage is greater than the first supply voltage.

5. The PLL of claim 1, wherein the charge pump comprises:
a current source, supplied by the second supply voltage;
a first differential pair circuit, coupled to the current source; and
a second differential pair circuit, coupled to the first differential pair circuit at a first node and a second node, one of the first node and the second node serving as an output node of the charge pump for outputting the control signal.

6. The PLL of claim 5, wherein the detect signal generated from the phase detector includes a first detect signal and a second detect signal, and the charge pump generates the control signal according to the first detect signal, the second detect signal, an inverted first detect signal and an inverted second detect signal, where the first detect signal and the inverted first detect signal are inputted to the first differential pair circuit, and the second detect signal and the inverted second detect signal are inputted to the second differential pair circuit.

7. The PLL of claim 5, wherein the charge pump further comprises:
a buffer amplifier, supplied by the second supply voltage and coupled between the first node and the second node.

8. A phase-locked loop (PLL), comprising:
a phase detector, for comparing a phase difference between a reference input signal and a feedback signal based on an output signal to generate at least one detect signal;
a charge pump, for generating a control signal with charge amounts according to the detect signal; and
a controllable oscillator, for generating the output signal according to the control signal, wherein a frequency of the output signal is adjusted by the control signal;
wherein the charge pump comprises at least one input/output (I/O) device and each transistor included in the phase detector is a core device.

9. The PLL of claim 8, further comprising:
a frequency divider, for dividing the output signal to generate the feedback signal.

10. The PLL of claim 8, further comprising:
a filter, for filtering the control signal before the controllable oscillator, wherein the filter comprises at least one I/O device.

11. The PLL of claim 8, wherein an operating voltage of the I/O device is greater than an operating voltage of the core device.

12. The PLL of claim 8, wherein the charge pump comprises:
a current source, supplied by an input/output (I/O) supply voltage;
a first differential pair circuit, coupled to the current source;
a second differential pair circuit, coupled to the first differential pair circuit at a first node and a second node, one of the first node and the second node serving as an output node of the charge pump for outputting the control signal.

13. The PLL of claim 12, wherein the detect signal generated from the phase detector includes a first detect signal and a second detect signal, and the charge pump generates the control signal according to the first detect signal, the second detect signal, an inverted first detect signal and an inverted second detect signal, where the first detect signal and the inverted first detect signal are inputted to the first differential pair circuit, and the second detect signal and the inverted second detect signal are inputted to the second differential pair circuit.

14. The PLL of claim 12, wherein the charge pump further comprises:
a buffer amplifier, supplied by the I/O supply voltage and coupled between the first node and the second node.
